(19) United States
(12) Patent Application Publication
(10) Pub. No.: US 2009/0232178 A1
(43) Pub. Date: Sep. 17, 2009

(54) TWO-WAVELENGTH SEMICONDUCTOR LASER DEVICE

(76) Inventors: Koichi HAYAKAWA, Okayama (JP); Toru Takayama, Hyogo (JP); Masahiro Kume, Shiga (JP); Tomoya Satoh, Osaka (JP); Isao Kidoguchi, Hyogo (JP)

Correspondence Address: MCDERMOTT WILL & EMERY LLP, 600 13TH STREET, NW, WASHINGTON, DC, 20005-3096, US

(21) Appl. No.: 12/392,469

(22) Filed: Feb. 25, 2009

(30) Foreign Application Priority Data
Mar. 14, 2008 (JP) 2008-066095

(51) Int. Cl. H01S 5/327

(52) U.S. Cl. 372/50.121

(57) ABSTRACT

A semiconductor laser device has a first light emitting portion and a second light emitting portion having a longer emission wavelength than that of the first light emitting portion. Each of the first light emitting portion and the second light emitting portion has a stripe-shaped ridge structure used for carrier injection. The ridge structure in the first light emitting portion includes a first front end region having a width Wf1 and having a length L3 from a front facet, a first rear end region having a width Wr1 and having a length L1 from a rear facet, and a first tapered region located between the first front end region and the first rear end region and having a length L2, and the relation of Wf1>Wr1 is satisfied. The ridge structure in the second light emitting portion includes a second front end region having a width Wf2 and having a length L6 from a front facet, a second rear end region having a width Wr2 and having a length L4 from a rear facet, and a second tapered region located between the second front end region and the second rear end region and having a length L5, and the relation of Wf2>Wr2 is satisfied. The relations of L1+L2+L3=L4+L5+L6, Wf1<Wf2, and L1>L4 are also satisfied.

### CROSS-REFERENCE TO RELATED APPLICATIONS

This application claims priority under 35 U.S.C. §119(a) on Japanese Patent Application No. 2008-66095 filed on Mar. 14, 2008, the entire contents of which are hereby incorporated by reference.

### BACKGROUND

High-capacity digital versatile discs (DVDs) capable of recording at a high density and DVD devices for playing such DVDs have been commercialized and have attracted attention as products of growing demand. Due to the high density recording of the DVDs, an AlGaInP (aluminum gallium indium phosphide)-based semiconductor laser device having an emission wavelength of 650 nm is used as a laser light source for recording and playing the DVDs. Accordingly, an optical pickup of a conventional DVD device can neither record nor play recordable compact discs (CDRs) which are recorded and played by using an AlGaAs (aluminum gallium arsenide)-based semiconductor laser having an emission wavelength of 780 nm.

An optical pickup having lasers of two wavelengths mounted therein has therefore been employed. In this optical pickup, a 650 nm-band AlGaInP-based semiconductor laser (a red laser) and a 780 nm-band AlGaAs-based semiconductor laser (an infrared laser) are mounted as a laser chip in separate packages. A device capable of recording and playing both DVDs and CDRs has thus been implemented.

Such an optical pickup, however, has a large size because two separate packages of the AlGaInP-based semiconductor laser and the AlGaAs-based semiconductor laser are mounted. Accordingly, the size of a DVD device using such an optical pickup is increased.

In view of this problem, an integrated semiconductor light emitting device integrating a plurality of kinds of semiconductor light emitting elements is known in the art. In this integrated semiconductor light emitting device, the plurality of kinds of semiconductor light emitting elements have different emission wavelengths from each other, and the light emitting element structure of each semiconductor light emitting element is formed by semiconductor layers grown on the same substrate. An example of such an integrated semiconductor light emitting device is described in Japanese Patent Laid-Open Publication No. H11-186651 (hereinafter, referred to as Document 1).

FIG. 11 shows an example of the integrated semiconductor light emitting device described in Document 1. As shown in FIG. 11, in a conventional integrated semiconductor laser device 100, a 700 nm-band (e.g., 780 nm) AlGaAs-based semiconductor laser LD1 and a 600 nm-band (e.g., 650 nm) AlGaInP-based semiconductor laser LD2 are integrated in a separated state on the same n-type GaAs (gallium arsenide) substrate 101.

For example, a substrate having a (100) orientation or a substrate having a surface tilted at, for example, 5° to 15° from a (100) face as a main surface is used as the n-type GaAs substrate 101.

In the AlGaAs-based semiconductor laser LD1, an n-type GaAs buffer layer 111, an n-type AlGaAs cladding layer 112, an active layer 113 having a single quantum well (SQW) structure or a multiple quantum well (MQW) structure, a p-type AlGaAs cladding layer 114, and a p-type GaAs cap layer 115 are sequentially formed in this order on the n-type GaAs substrate 101.

An upper part of the p-type AlGaAs cladding layer 114 and the p-type GaAs cap layer 115 form a stripe shape extending in one direction. An n-type GaAs current confinement layer 116 is formed on both sides of the stripe portion, whereby a current confinement structure is formed. A p-side electrode 117 is provided on the stripe-shaped p-type GaAs cap layer 115 and the n-type GaAs current confinement layer 116 and has ohmic contact with the p-type GaAs cap layer 115. For example, a Ti/Pt/Au (titanium/platinum/gold) electrode is used as the p-side electrode 117.

In the AlGaInP-based semiconductor laser LD2, an n-type GaAs buffer layer 121, an n-type AlGaInP cladding layer 122, an active layer 123 having an SQW structure or an MQW structure, a p-type AlGaInP cladding layer 124, a p-type GaInP (gallium indium phosphide) intermediate layer 125, and a p-type GaAs cap layer 126 are sequentially formed in this order on the n-type GaAs substrate 101.

An upper part of the p-type AlGaInP cladding layer 124, the p-type GaInP intermediate layer 125, and the p-type GaAs cap layer 115 form a stripe shape extending in one direction. An n-type GaAs current confinement layer 127 is formed on both sides of the stripe portion, whereby a current confinement structure is formed. A p-side electrode 128 is provided on the stripe-shaped p-type GaAs cap layer 126 and the n-type GaAs current confinement layer 127 and has ohmic contact with the p-type GaAs cap layer 126. For example, a Ti/Pt/Au electrode is used as the p-side electrode 128.

An n-side electrode 129 is provided on the back surface of the n-type GaAs substrate 101 and has ohmic contact with the n-type GaAs substrate 101. For example, an AuGe/Ni (gold-germanium/nickel) electrode or an In (indium) electrode is used as the n-side electrode 129.

The p-side electrode 117 of the AlGaAs-based semiconductor laser LD1 and the p-side electrode 128 of the AlGaInP-based semiconductor laser LD2 are respectively soldered on a heat sink H1 and a heat sink H2 by AuSn (gold-tin) or the like. The heat sink H1 and the heat sink H2 are provided on a package base so as to be electrically isolated from each other.

In the conventional integrated semiconductor laser device 100 described above, the AlGaAs-based semiconductor laser LD1 can be driven by applying a current between the p-side electrode 117 and the n-side electrode 129. The AlGaInP-based semiconductor laser LD2 can be driven by applying a current between the p-side electrode 128 and the n-side electrode 129. Laser light of a 700 nm band (e.g., 780 nm) can be obtained by driving the AlGaAs-based semiconductor laser LD1, and laser light of a 600 nm band (e.g., 650 nm) can be obtained by driving the AlGaInP-based semiconductor laser LD2. Whether the AlGaAs-based semiconductor laser LD1 or the AlGaInP-based semiconductor laser LD2 is driven is selected by, for example, switching an external switch.

As described above, the conventional integrated semiconductor laser device 100 has the 700 nm-band AlGaAs-based semiconductor laser LD1 and the 600 nm-band AlGaInP-based semiconductor laser LD2 on the same substrate. Accordingly, laser light for DVDs and laser light for CDs can be independently obtained. Playing and recording of both DVDs and CDs is therefore enabled by mounting the integrated semiconductor laser device 100 as a laser light source on an optical pickup of a DVD device.

The respective laser structures of the AlGaAs-based semiconductor laser LD1 and the AlGaInP-based semiconductor laser LD2 are formed by semiconductor layers grown over the same n-type GaAs substrate 101. Therefore, only one package is required for this integrated semiconductor laser device. This enables reduction in size of an optical pickup and therefore reduction in size of a DVD device.

A semiconductor laser needs to have high optical output in order to rewrite an optical disc at a high speed. For example, in order to rewrite a DVD optical disc at a 16-fold speed or higher, a semiconductor laser is required to have optical output as high as 240 mW or more. In order to obtain such high output, it is necessary to prevent COD (Catastrophic Optical Damage), a phenomenon in which facets of a semiconductor laser are melted and destroyed due to high optical output of the semiconductor laser itself during high power operation.

In order to prevent COD, it is effective to reduce the light density inside the cavity facets of a laser to suppress heat generation. A known method for this is to reduce the reflectance of the front facet of a semiconductor laser, i.e., the facet from which laser light is obtained, by coating the front facet with a dielectric material such as SiO₂ (silicon oxide) or Al₂O₃ (aluminum oxide).

In general, a semiconductor laser device made of an AlGaInP-based material or an AlGaAs-based material has a reflectance of about 30% at the cavity facets unless the facets are coated. In this case, about 30% of laser light is reflected at the cavity facets and fed back into the cavity, while the remaining laser light, that is, about 70% of laser light, is obtained from the front facet.

On the other hand, in the case where dielectric film coating is performed so that the front facet has a reflectance of, for example, 6%, 6% of laser light is reflected at the front facet and fed back into the cavity, while the remaining laser light, that is, 94% of laser light, is obtained from the front facet.

In other words, provided that the light output obtained from the front facet is the same, the light density at the cavity facets can be reduced to one fifth if the reflectance at the front facet is reduced to one fifth. Reducing the reflectance at the front facet leads to increase in COD level and is therefore effective means for obtaining a high power laser. Moreover, when the rear facet, that is, the facet located on the opposite side to the cavity face from which laser light is obtained, has a high reflectance, light can be more efficiently obtained from the front facet of the semiconductor laser.

In a high power semiconductor laser, the facet coating is usually performed under such conditions that reduce the reflectance of the front facet and increase the reflectance of the rear facet.

In order to obtain high power operation of a two-wavelength laser integrating an red semiconductor laser and an infrared semiconductor laser on the same substrate, the laser cavity facets are coated with a dielectric film for the above-described reason so as to simultaneously obtain a high reflectance at the front facet and a low reflectance at the rear facet in each of the red light emitting portion and the infrared light emitting portion.

### SUMMARY

It is expected that there will be a growing demand for optical pickups having mounted therein three lasers, that is, a blue-violet laser for recording and playing 16-fold-speed or higher DVDs and BDs (Blu-ray Discs) at a high density, a red laser for DVDs, and an infrared laser for CDs. In such optical pickups, high power operation of at least 300 mW is required for the red laser used as a light source. The reason for this is as follows: since the transmission efficiency and characteristics of an optical system need to be optimized for the blue-violet laser for recording BDs, optical power loss of the red laser and the infrared laser is increased, and higher optical output is required.

In general, laser light emitted from a semiconductor laser has a wider spread angle in a vertical direction to an active layer than in a horizontal direction thereto. More specifically, the vertical spread angle is about 14° to about 16° and the horizontal spread angle is about 6° to about 11°. Laser light emitted from the semiconductor laser thus spread in an oval shape. If the ellipticity (aspect ratio) is large, the amount of light collected by a collective lens is reduced and the focusing spot diameter is increased.

Since the red laser is required to have higher light collecting characteristics and higher recording power than those of the infrared laser, the horizontal spread angle of the red laser is set to 8° to 11° and the horizontal spread angle of the infrared laser is set to 6° to 11° in order to reduce the aspect ratio of the red laser.

In order to satisfy these characteristics, the stripe width of the facet (front facet), that is, the facet from which laser light is obtained, is made narrower in the red laser than in the infrared laser. By thus reducing the stripe width to reduce the laser light confinement width in the horizontal direction, the spread angle of laser light emitted from the facet is increased by diffraction.

In order to obtain high output exceeding 300 mW, it is necessary to prevent non-linearity called a “kink” from occurring in optical output characteristics with respect to a current (I-L characteristics) when a current is increased. A kink is generated because the refractive index for confining light is varied by a high current density and a high light density within the stripe and a light distribution profile in a basic mode is disturbed. The following structure has been proposed to increase the optical output that causes a kink (the kink level) (e.g., Japanese Patent Laid-Open Publication No. 2006-114605). In the proposed structure, the stripe width of the rear facet side, that is, the stripe width of the opposite side to the front facet from which light is obtained to the outside, is made narrower than the stripe width of the front facet side, whereby optical distribution in the basic mode is maintained up to high output.

An example of a semiconductor laser element having this structure is shown in FIG. 12. FIG. 12 schematically shows a planar shape of a stripe. A stripe 213 has a front end region 216, a transition region 215, and a rear end region 214.

The front end region 216 is a region from a front facet 221 to the position of a length L12, and has a uniform stripe width W12. The rear end region 214 is a region from a rear facet 222 to the position of a length L11, and has a uniform stripe width W11. The transition region 215 is a region located between the front end region 216 and the rear end region 214 and connecting the front end region 216 and the rear end region 214 together, and has a length L13. In this region 215, the stripe width is reduced from the stripe width W12 of the front end region 216 to the stripe width W11 of the rear end region 214.

If the length L11 of the rear end region 214 having a narrow stripe width (W11) is increased, the stripe region to which a current is injected will have a reduced area. As a result, the operating voltage of the element will be increased. If the length L13 of the transition region 215 is reduced, the transition angle θ from the rear end region 214 having a narrow stripe width (W11) to the front end region 216 having a wide stripe width (W12) will be increased. As a result, light scattering loss in the stripe will be increased. This will cause reduction in slope efficiency, that is, light output efficiency with respect to a current.

In view of the above, it is important to optimally design a semiconductor laser device so that characteristics such as a driving voltage, slope efficiency, and a kink level are satisfied.

Since the semiconductor laser element of the example of FIG. 12 is a single-wavelength laser (a 400 nm-band blue-violet laser), it is easy to design the laser so as to obtain optimal characteristics.

However, in the case of a two-wavelength semiconductor laser device having a red laser and an infrared laser on the same substrate as in the example of FIG. 11, the red laser and the infrared laser have the same cavity length. Therefore, problems that do not occur in a single-wavelength laser occur in the two-wavelength semiconductor laser device.

As compared to an infrared laser, a red laser generally has problems in terms of characteristics, such as a low kink level, poor temperature characteristics (large increase in threshold value, operating current, and the like when the temperature increases), and a higher operating voltage. Accordingly, the threshold current density and the operating current density are reduced by increasing the cavity length.

However, if the cavity length is increased in order to improve characteristics of the red laser in the two-wavelength semiconductor laser device, the cavity length of the infrared laser will become longer than the cavity length for obtaining optimal characteristics. This causes degradation in slope characteristics and increase in operating current in the infrared laser.

In view of the above, description will now be given to a high power semiconductor laser device integrating a plurality of lasers such as a red laser and an infrared laser on the same substrate and capable of obtaining high output of at least 300 mW or the like while achieving optimization of characteristics of each laser such as improvement in kink level, reduction in operating voltage, improvement in temperature characteristics, setting of the vertical spread angle of emitted light.

In a semiconductor laser device according to the present invention, a first light emitting portion and a second light emitting portion that emits light at a longer wavelength than that of the first light emitting portion are provided on a substrate. Each of the first light emitting portion and the second light emitting portion includes a first conductive type cladding layer, an active layer formed on the first conductivity type cladding layer, and a second conductivity type cladding layer formed on the active layer and having a stripe-shaped ridge structure for carrier injection. The ridge structure in the first light emitting portion includes a first front end region having a width Wf1 and having a length L3 from a front facet, a first rear end region having a width Wr1 and having a length L1 from a rear facet, and a first tapered region located between the first front end region and the first rear end region, having a width varied from the front facet side toward the rear facet side, and having a length L2, and the relation of Wf1>Wr1 is satisfied. The ridge structure in the second light emitting portion includes a second front end region having a width Wf2 and having a length L6 from a front facet, a second rear end region having a width Wr2 and having a length L4 from a rear facet, and a second tapered region located between the second front end region and the second rear end region, having a width varied from the front facet side toward the rear facet side, and having a length L5, and the relation of Wf2>Wr2 is satisfied. The relations of L1+L2+L3=L4+L5+L6, Wf1<Wf2, and L1>L4 are also satisfied.

In other words, in the stripe-shaped ridge structure of the first light emitting portion, the regions at both cavity ends (the first front end region and the first rear end region) have a substantially uniform width (stripe width) of Wf1 and Wr1 (Wf1>Wr1), respectively, and the first tapered region located therebetween has a width varied from Wf1 of the front end side to Wr1 of the rear end side.

Similarly, in the stripe-shaped ridge structure of the second light emitting portion, the regions at both cavity ends (the second front end region and the second rear end region) have a substantially uniform width of Wf2 and Wr2 (Wf2>Wr2), respectively, and the second tapered region located therebetween has a width varied from Wf2 of the front end side to Wr2 of the rear end side.

Moreover, the width at the front facet in the ridge structure of the first light emitting portion (the width Wf1 of the first front end region) is narrower than the width at the front facet in the ridge structure of the second light emitting portion (the width Wf2 of the second front end region), and the length L1 of the first rear end region is longer than the length L4 of the second rear end region.

With the above structure, reduction in operating voltage, improvement in temperature characteristics, and improvement in kink level can be implemented and horizontal spread of laser output can be adjusted in the first light emitting portion and the second light emitting portion. As a result, the semiconductor laser device can be optimized as a semiconductor laser device having a plurality of light emitting portions. Moreover, the light emission efficiency is improved and a high COD level is achieved, whereby high output of, for example, 300 mW or more can be obtained. The reason for this will now be described.

First, increasing the width of the stripe formed by the ridge structure reduces the series resistance of the element, thereby reducing the operating voltage. As a result, the slope efficiency in the current-optical output characteristics is improved, whereby excellent temperature characteristics can be obtained. Especially when the light reflectance at the front facet of the cavity is lower than that at the rear facet of the cavity, the light density inside the cavity becomes higher toward the front facet. Accordingly, the effect of increasing the current injection amount by increasing the width of the ridge structure (and the stripe) becomes significant on the front facet side.

However, since strong induced emission occurs in the middle region of the width direction of the stripe, the carrier density is reduced in the middle region and the distribution has a recessed profile. This phenomenon causes generation of a kink, and such kink generation becomes more significant as the stripe width becomes wider. In order to suppress kink generation, it is desirable that the stripe has a narrower width.

In view of the above, it is desirable that the width of the ridge structure is varied so that the width on the front facet side becomes wider than that on the rear facet side. It should be noted that, in the case where the width is varied, scattering loss of guided waves at the sidewalls is increased, whereby the efficiency is degraded. It is especially preferable that variation in width is small in the region close to the front facet having a high light density. It is more preferable that the ridge structure includes a region having a substantially uniform width.

In view of the above, it is desirable that, in both of the first light emitting portion and the second light emitting portion, the regions near both ends (front and rear ends) of the cavity in the ridge structure have a uniform width, one of the regions (the region on the front end side) is wider than the other region (the region on the rear end side), and a region having a varying width is provided between these regions.

Since the second light emitting portion emits light at a longer wavelength than that of the first light emitting portion, it is necessary to reduce the horizontal spread angle of laser light emitted from the first light emitting portion. In order to implement this, the width Wf1 at the front facet in the first stripe structure is made narrower than the width Wf2 at the front facet in the second stripe structure.

Similarly, due to the difference in emission wavelength, it is more important to reduce the kink level in the first light emitting portion than to reduce the kink level in the second light emitting portion. In order to implement this, the length L1 of the first rear end region is made longer than the length L4 of the second rear end region. In other words, the length of the rear end portion of the stripe is increased since the narrow width of the rear end portion is effective to reduce the kink level.

It is preferable that the relations of L3>L2 and L5>L6 are satisfied.

In other words, it is preferable that the first front end region (length L3) is longer than the first tapered region (length L2) and the second tapered region (length L5) is longer than the second front end region (length L6).

Since the emission wavelength is different between the first light emitting portion and the second light emitting portion, the above structure is preferable in order to optimally reduce the operating voltage and optimally improve the slope efficiency in the first light emitting portion and the second light emitting portion.

It is preferable that, provided that Rf is a reflectance at the front facet and Rr is a reflectance at the rear facet, the relation of Rf<Rr is satisfied.

In this case, the emission efficiency can be improved and a high COD level can be implemented in both the first light emitting portion and the second light emitting portion.

It is preferable that the first front end region, the first rear end region, the second front end region, and the second rear end region are shaped so that variation in width is within ±10%.

In these regions having a substantially constant width, it is desirable that the width is varied, for example, within such a range.

It is preferable that, in both of the first light emitting portion and the second light emitting portion, the first conductivity type cladding layer and the second conductivity type cladding layer are both made of an AlGaInP-based material.

These cladding layers may be made of, for example, the above material. The ridge that forms the stripe can be formed in both the first light emitting portion and the second light emitting portion by a common process. Therefore, the manufacturing process can be simplified and the manufacturing cost can be reduced.

It is preferable that the active layer in the first light emitting layer is made of a GaInP-based or AlGaInP-based material and the active layer in the second light emitting layer is made of a GaAs-based or AlGaAs-based material.

A semiconductor laser device having a first light emitting portion for emitting light in a red range and a second light emitting portion for emitting light in an infrared range can thus be obtained.

It is preferable that the active layer in at least one of the first light emitting portion and the second light emitting portion is a quantum well active layer, and the quantum well active layer is disordered by impurity diffusion in a vicinity of at least one of a front facet and a rear facet of a cavity including the quantum well active layer.

As described above, the active layer may be a quantum well active layer. Since a region disordered by impurity diffusion (a window region) is provided, non-light-emitting recombination that does not contribute to laser oscillation in the window region is reduced, whereby heat generation of the element in the window region can be suppressed. As a result, reduction in COD level can be prevented.

According to the semiconductor laser device as described above, in a semiconductor laser device having a plurality of light emitting portions such as a red laser and an infrared laser, a desired horizontal spread angle is satisfied in each light emitting portion, whereby the series resistance of the element is reduced and the operating voltage is reduced. As a result, the kink level required for high power operation can be obtained. Moreover, the emission efficiency is improved and a high COD level is achieved, whereby output as high as, for example, 300 mW or more can be obtained. A semiconductor laser device integrating a plurality of light emitting portions can therefore be manufactured by a simplified manufacturing process, whereby high yield and low cost can be implemented.

### BRIEF DESCRIPTION OF THE DRAWINGS

FIG. 1A schematically shows a cross-sectional structure of an example semiconductor laser device, and FIGS. 1B and 1C show a layered structure of an active layer of a red laser and a layered structure of an active layer of an infrared laser, respectively;

FIG. 2 schematically shows a ridge shape of the example semiconductor laser device;

FIG. 3 shows generation of spatial hole burning of operating carriers in the active layer;

FIG. 4A shows the relation between the ridge width at the front facet of the red laser and the horizontal spread angle, and FIG. 4B shows the relation between the ridge width at the front facet of the infrared laser and the horizontal spread angle;

FIG. 5A shows the relation between the length of a rear end region in the red laser and the kink level, and FIG. 5B shows the relation between the length of a rear end region in the infrared laser and the kink level;

FIG. 6A shows the relation between the length of a front edge region in the red laser and the operating voltage, and FIG. 6B shows the relation between the length of a front edge region in the infrared laser and the operating voltage;

FIGS. 7A and 7B show current-optical output characteristics in the red laser and the infrared laser, respectively;

FIGS. 8A, 8B, and 8C illustrate a manufacturing process of the example semiconductor laser device;

FIGS. 9A, 9B, and 9C illustrate the manufacturing process of the example semiconductor laser device after FIG. 8C;

FIGS. 10A and 10B illustrate the manufacturing process of the example semiconductor laser device after FIG. 9C;

FIG. 11 shows an example of a semiconductor laser device of related art; and

FIG. 12 shows a stripe shape of a semiconductor device of related art.

### DETAILED DESCRIPTION

Hereinafter, a semiconductor device of the disclosure will be described with reference to the accompanying drawings.

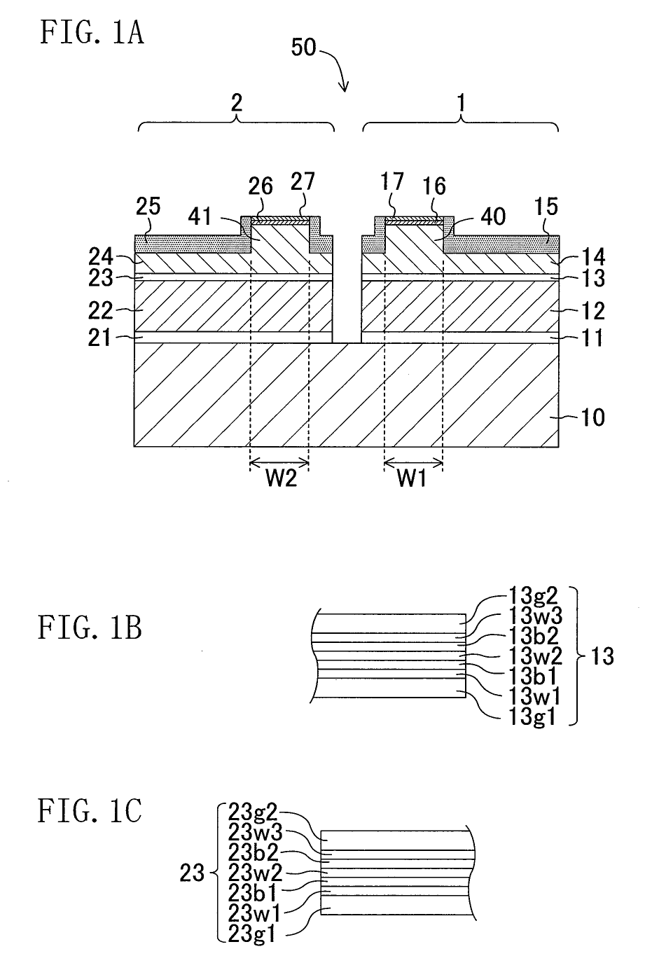

FIG. 1A is a schematic view showing a cross-sectional structure of an example semiconductor laser device 50.

In the semiconductor laser device 50, a red laser 1 and an infrared laser 2 are integrated on an n-type GaAs substrate 10 as two light emitting portions for emitting light at different wavelengths from each other. The n-type GaAs substrate 10 has a surface tilted at 10 degrees from a (100) face in a [011] direction as a main surface.

First, the structure of the red laser 1 will be described. In the red laser 1, an n-type buffer layer 11 (thickness: 0.5 μm), an n-type cladding layer 12 (thickness: 2.0 μm), an active layer 13, a p-type cladding layer 14, a p-type protective layer 16 (thickness: 50 nm), and a p-type contact layer 17 (thickness: 0.4 μm) are sequentially formed on an n-type GaAs substrate 10 in this order from the bottom. The n-type buffer layer 11 is made of n-type GaAs, and the n-type cladding layer 12 is made of n-type (Al_{0.7}Ga_{0.3})_{0.51}In_{0.49}P. The active layer 13 has a strained quantum well structure. The p-type cladding layer 14 is made of p-type (Al_{0.7}Ga_{0.3})_{0.51}In_{0.49}P, the p-type protective layer 16 is made of p-type Ga_{0.51}In_{0.49}P, and the p-type contact layer 17 is made of p-type GaAs.

The p-type cladding layer 14 has a mesa-shaped ridge portion 40. The p-type protective layer 16 and the p-type contact layer 17 are formed over the ridge portion 40. A current block film 15 (thickness: 0.3 μm) made of an SiN (silicon nitride) dielectric film is formed so as to cover the sidewalls of the ridge portion 40 and the p-type cladding layer 14 other than the ridge portion 40. Note that the width of the ridge portion 40 is denoted by W1.

In the p-type cladding layer 14, the distance from the upper end of the ridge portion 40 to the active layer 13 is 1.4 μm, and the distance from the lower end of the ridge portion 40 to the active layer 13 is dp (0.2 μm).

The active layer 13 is a strained quantum well active layer and has the structure shown in FIG. 1B. More specifically, the active layer 13 has a layered structure of three well layers 13w1, 13w2, and 13w3 (thickness of each well layer: 5 nm), two barrier layers 13b1 and 13b2 (thickness of each barrier layer: 5 nm), a first guide layer 13g1, and a second guide layer 13g2 (thickness of each guide layer: 50 nm). The well layers 13w1, 13w2, and 13w3 are made of Ga_{0.48}In_{0.52}P, the barrier layers 13b1 and 13b2 are made of (Al_{0.5}Ga_{0.5})_{0.51}In_{0.49}P, and the first guide layer 13g1 and the second guide layer 13g2 are made of (Al_{0.5}Ga_{0.5})_{0.51}In_{0.49}P. The barrier layer 13b1 is interposed between the well layers 13w1 and 13w2, and the barrier layer 13b2 is interposed between the well layers 13w2 and 13w3. The first guide layer 13g1 and the second guide layer 13g2 are respectively formed under and over the five-layered structure of the well layers 13w1, 13w2, and 13w3 and the barrier layers 13b1 and 13b2 so that the five-layered structure is interposed between the first guide layer 13g1 and the second guide layer 13g2.

In this structure, a current injected from the p-type contact layer 17 is confined only in the mesa-shaped ridge portion 40 by the current block film 15. The current is therefore injected intensively into the active layer 13 in a stripe portion located under the ridge portion 40. As a result, an inverted population state of carriers which is required for laser oscillation is implemented by an injected current as small as about several tens of milliamperes.

Light emitted by recombination of carriers injected into the active layer 13 is confined by the n-type cladding layer 13 and the p-type cladding layer 14 in a vertical direction to the active layer 13. At the same time, the light is confined in a horizontal direction to the active layer 13 because the current block layer 15 has a lower refractive index than that of the n-type cladding layer 12 and the p-type cladding layer 14.

The current block film 15 is transparent to laser oscillation light. No light is therefore absorbed in the current block film 15 and a low-loss waveguide can be implemented. Distribution of light propagated through the waveguide can significantly permeate the current block film 15. Therefore, Δn on the order of 10⁻³, which is a refractive index difference suitable for high power operation, can be easily obtained. Moreover, Δn can be precisely controlled on the order of 10⁻³ by controlling the value dp.

The red laser 1 is therefore a high power semiconductor laser capable of precisely controlling light distribution and having a low operating current.

The infrared laser 2 has the same structure as that of the red laser 1 except for the structure of the active layer and operates in the same manner as that of the red laser 1 except for the emission wavelength. The infrared laser 2 will now be described in detail.

In the infrared laser 2, an n-type buffer layer 21 (thickness: 0.5 μm), an n-type cladding layer 22 (thickness: 2.0 μm), an active layer 23, a p-type cladding layer 24, a p-type protective layer 26 (thickness: 50 nm), and a p-type contact layer 27 (thickness: 0.4 μm) are sequentially formed on the same n-type GaAs substrate 10 as that of the red laser 1 in this order from the bottom. The n-type buffer layer 21 is made of n-type GaAs, and the n-type cladding layer 22 is made of n-type (Al_{0.7}Ga_{0.3})_{0.51}In_{0.49}P. The active layer 23 has a quantum well structure. The p-type cladding layer 24 is made of p-type (Al_{0.7}Ga_{0.3})_{0.51}In_{0.49}P, the p-type protective layer 26 is made of p-type Ga_{0.51}In_{0.49}P, and the p-type contact layer 27 is made of p-type GaAs.

The p-type cladding layer 24 has a mesa-shaped ridge portion 41. The p-type protective layer 26 and the p-type contact layer 27 are formed over the ridge portion 41. A current block layer 25 (thickness: 0.3 μm) made of an n-type AlInP (aluminum indium phosphide) is formed so as to cover the sidewalls of the ridge portion 41 and the p-type cladding layer 24 other than the ridge portion 41. Note that the width of the ridge portion 41 is denoted by W2.

In the p-type cladding layer 24, the distance from the upper end of the ridge portion 41 to the active layer 23 is 1.4 μm, and the distance from the lower end of the ridge portion 41 to the active layer 23 is dp (0.24 μm).

The active layer 23 is a quantum well active layer and has the structure shown in FIG. 1C. More specifically, the active layer 23 has a layered structure of three well layers 23w1, 23w2, and 23w3, two barrier layers 23b1 and 23b2, a first guide layer 23g1, and a second guide layer 23g2. The well layers 23w1, 23w2, and 23w3 are made of GaAs, the barrier layers 23b1 and 23b2 are made of Al_{0.5}Ga_{0.5}As, and the first guide layer 23g1 and the second guide layer 23g2 are made of Al_{0.5}Ga_{0.5}As. The barrier layer 23b1 is interposed between the well layers 23w1 and 23w2, and the barrier layer 23b2 is interposed between the well layers 23w2 and 23w3. The first guide layer 23g1 and the second guide layer 23g2 are respectively located under and over the five-layered structure of the well layers 23w1, 23w2, and 23w3 and the barrier layers 23b1 and 23b2 so that the five-layered structure is interposed between the first guide layer 23g1 and the second guide layer 23g2.

In this structure as well, a current injected from the p-type contact layer 27 is confined only in the mesa-shaped ridge portion 41 by the current block film 25, as in the red laser 1. The current is therefore injected intensively into the active layer 23 in a region located under the ridge portion 41. As a result, an inverted population state of carriers which is required for laser oscillation is implemented by an injected current as small as about several tens of milliamperes.

Light emitted by recombination of carriers injected into the active layer 23 is confined in the same manner as that in the red laser 1. More specifically, the light is confined by the n-type cladding layer 22 and the p-type cladding layer 24 in the vertical direction to the active layer 23. At the same time, the light is confined in the horizontal direction to the active layer 23 because the current block layer 25 has a lower refractive index than that of the n-type cladding layer 22 and the p-type cladding layer 24.

The current block film 25 is transparent to laser oscillation light. No light is therefore absorbed in the current block film 25 and a low-loss waveguide can be implemented. Moreover, as in the red laser 1, distribution of light propagated through the waveguide can permeate the current block film 25. Therefore, Δn on the order of 10⁻³, which is a refractive index difference suitable for high power operation, can be easily obtained. Moreover, Δn can be precisely controlled on the order of 10⁻³ by controlling the value dp.

The infrared laser 2 is therefore a high power semiconductor laser capable of precisely controlling light distribution and having a low operating current.

In order to improve the heat release capability during high temperature operation of, for example, 80° C., the operating current density is reduced by setting the cavity length to 1,500 μm or more in the case of a high power laser of 300 mW or higher. More specifically, the cavity length is set to 1,700 μm both in the red laser 1 and the infrared laser 2.

In the red laser 1 and the infrared laser 2, coating with a dielectric film is performed so that the reflectance at the front facet of the cavity becomes 7% and the reflectance at the rear facet of the cavity becomes 94% for red laser light and infrared laser light, respectively.

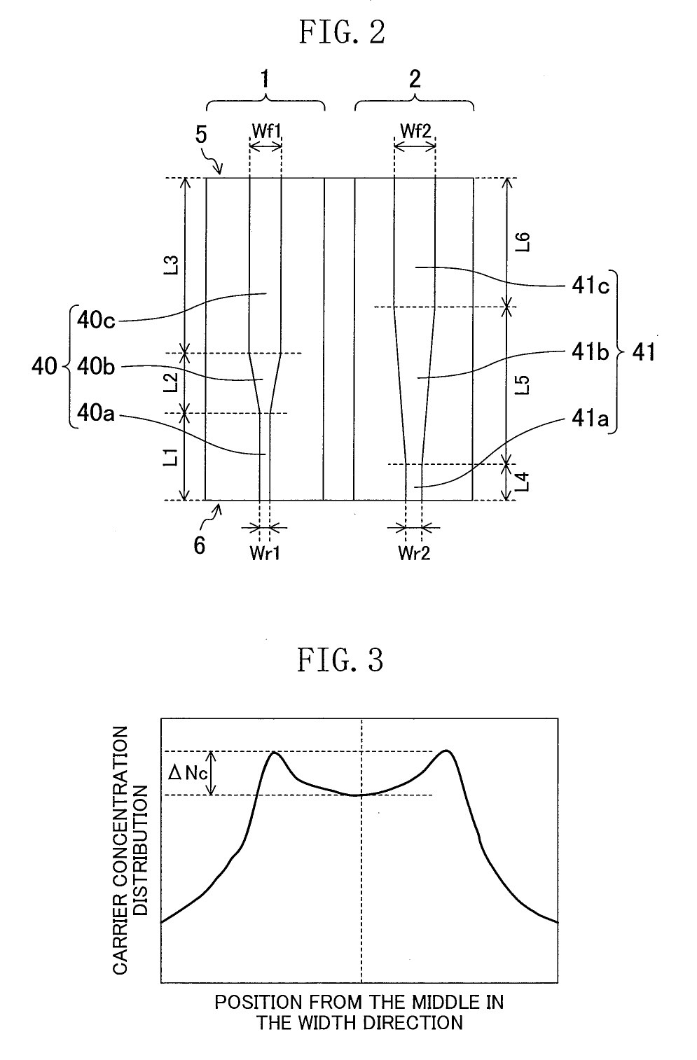

A planar structure of the semiconductor laser device 50 will now be described with reference to FIG. 2. FIG. 2 shows respective stripe shapes of the mesa-shaped ridge portion 40 in the red laser 1 and the mesa-shaped ridge portion 41 in the infrared laser 2 when the semiconductor laser device 50 is viewed from the ridge portion 40 side. Laser light is emitted from a front facet 5. The opposite side to the front facet 5 is a rear facet 6.

As shown in FIG. 2, each of the ridge portion 40 of the red laser 1 and the ridge portion 41 of the infrared laser 2 has end regions located at both ends and respectively contacting the front facet 5 and the rear facet 6, and a region interposed between these regions. Each of the end regions has a substantially uniform width, and the region interposed between the end regions has a tapered shape.

More specifically, the ridge portion 40 of the red laser 1 has a red-side front end region 40c, a red-side rear end region 40a, and a red-side tapered region 40b. The red-side front end region 40c is in contact with the front facet 5 and has a length L3 and a uniform width Wf1 (e.g., 3.5 μm). The red-side rear end region 40a is in contact with the rear facet 6 and has a length L1 and a uniform width Wr1 (e.g., 2.1 μm which is narrower than Wf1). The red-side tapered region 40b connects the red-side front end region 40c and the red-side rear end region 40a and has a length L2. The width of the red-side tapered region 40b is gradually reduced from Wf1 of the front facet 5 side to Wr1 of the rear facet 6 side.

Similarly, the ridge portion 41 of the red laser 2 has an infrared-side front end region 41c, an infrared-side rear end region 41a, and an infrared-side tapered region 41b. The infrared-side front end region 41c is in contact with the front facet 5 and has a length L6 and a uniform width Wf2 (e.g., 4.5 μm). The infrared-side rear end region 41a is in contact with the rear facet 6 and has a length L4 and a uniform width Wr2 (e.g., 2.1 μm which is narrower than W2f). The infrared-side tapered region 41b connects the infrared-side front end region 41c and the infrared-side rear end region 41a and has a length L5. The width of the infrared-side tapered region 41b is gradually reduced from Wf2 of the front facet 5 side to Wr2 of the rear facet 6 side (the rear side).

Note that the ridge width indicates the width at the lower end of the ridge portion 40, 41 shown by W1, W2 in FIG. 1. In the case where the side surfaces of the ridge extend vertically as shown in FIG. 1, the ridge width is equal to the stripe width. In the case where the side surfaces of the ridge do not extend vertically, the width at the bottom of the ridge portion is the stripe width.

The ridge width can be considered to be substantially uniform when variation of the ridge width is within about ±10%.

Although not specifically shown in the figures, impurities are diffused near both cavity facets in the active layer 13 of the red laser 1 and the active layer 23 of the infrared laser 2. Zn (zinc) is used as the impurities. A disordered window region is formed by this impurity diffusion. The length of the window region (the dimension in the longitudinal direction of the cavity) is about 20 μm both in the red laser 1 and the infrared laser 2. This length is short enough with respect to the cavity length of 1,700 μm and the influence of this length on characteristics is small enough to be negligible in the discussion given below.

Hereinafter, the respective planar shapes of the ridge portions 40 and 41 and the effects thereof will further be described.

In a high power semiconductor laser, coating with a dielectric film is generally performed so that the reflectance (Rf) at the front facet 5 becomes as low as 10% or less and the reflectance (Rr) at the rear facet 6 becomes as high as 75% or more. This improves the efficiency at which light is obtained from the front facet 5, and reduces the light density near the front facet 5, whereby the optical output level that causes the facets of the laser to be melted and destroyed (COD) is increased.

In this case, the light density is higher on the front facet 5 side than on the rear facet 6 side in a cavity direction. The number of carriers consumed for laser oscillation in the active layer is therefore larger on the front facet 5 side than on the rear facet 6 side. Accordingly, by injecting a larger current to the front facet 5 side having a relatively high light density in the cavity, the slope efficiency in the current-optical output characteristics is improved, whereby a laser element having excellent temperature characteristics can be obtained.

In view of the above, the ridge portions 40 and 41 are structured so that the ridge width on the front facet 5 side is wider than that on the rear facet 6 side. In other words, Wf1>Wr1 and Wf2>Wr2 are satisfied.

Hereinafter, the difference in ridge width between the front facet of the red laser 1 and the front facet of the infrared laser 2 (the difference between Wf1 and Wf2) will be described.

Requirements for light-collecting characteristics and recording power are stricter for the red laser 1 than for the infrared laser 2. The red laser 1 therefore needs to have a wider horizontal spread angle than that of the infrared laser 2 to reduce the aspect ratio. In order to implement this, the ridge width Wf1 at the front facet 5 of the red laser 1 is made narrower than the ridge width Wf2 at the front facet 5 of the infrared laser 2. In this example, Wf1 is 3.5 μm and Wf2 is 4.5 μm. The red laser 1 thus has a horizontal spread angle of 9° and the infrared laser 2 has a horizontal spread angle of 7.5°.

Hereinafter, the respective ridge widths (Wr1 and Wr2) at the rear facet 6 of the red laser 1 and the infrared laser 2 will be described. Horizontal distribution of the operating carrier density in the active layers (13 and 23) will now be considered. The light distribution intensity in the width direction of the ridge portion is highest in the middle and strong induced emission occurs in the middle. Accordingly, the carrier concentration is relatively reduced in the middle region of the stripe, and the carrier concentration distribution has a recessed profile as shown in FIG. 3. This phenomenon is called spatial hole burning of carriers.

The depth of the recess in the carrier concentration is denoted by ΔNc as shown in FIG. 3. As ΔNc becomes larger, the horizontal gain distribution in the active layer becomes lower in the middle region of the ridge portion and higher in the regions under the ridge ends. With such distribution, slight left-right (width direction) asymmetry of the ridge portion will cause light distribution to shift in a left-right direction, thereby causing a kink. In order to suppress such a phenomenon, it is desirable that the operating carrier density is low.

In general, the difference in bandgap energy between the active layer and the cladding layer is larger in the infrared laser 2 than in the red laser 1. Accordingly, the overflow of thermally excited carriers is smaller in the infrared laser 2 than in the red laser 1.

Moreover, provided that the injected carrier density is the same, an AlGaAs-based material used as a material of the active layer 23 of the infrared laser 2 has a larger gain than that of an AlGaInP-based material used as a material of the active layer 13 of the red laser 1.

In view of the above, during high temperature, high power operation, the operating carrier density is lower in the infrared laser 2 than in the red laser 1. Accordingly, provided that the ridge width is the same, a kink is less likely to be generated in the infrared laser 2 having better temperature characteristics than in the red laser 1 due to the lower operating carrier density.

As the ridge width is increased, the difference in oscillation threshold value between the basic mode and the higher-order mode of horizontal light distribution becomes smaller. Accordingly, transition to the higher-order mode is more likely to be caused by a change in refractive index distribution caused by the reduction ΔNc in carrier concentration in the middle of the ridge. The kink level is therefore reduced by increasing the ridge width.

The ridge width, on the other hand, affects the series resistance of the element. In other words, when the ridge width is wide, the current injection region becomes wide, whereby the series resistance of the element is reduced and the operating voltage is reduced. This reduces power consumption and also reduces the amount of heat generation, thereby contributing to improvement in temperature characteristics of the element. Moreover, the driving voltage of the laser can be reduced. Accordingly, the wide ridge width is advantageous in terms of circuit design.

In view of the above, it is desirable to design a semiconductor laser device so as to increase the ridge width as much as possible in such a range that does not cause reduction in king level.

Requirements for the planar shape of the ridge portions 40 and 41 in the semiconductor laser device 50 described above are listed below.

(1) In order to improve the slope efficiency in the current-optical output characteristics, it is desirable that the ridge width on the front end side is wider than that on the rear end side. In other words, it is desirable that the width Wf1 of the red-side front end region 40c and the width wf2 of the infrared-side front end region 41c are wider than the width Wr1 of the red-side rear end region 40a and the width Wr2 of the infrared-side rear end region 41a, respectively.

(2) In order to reduce the operating voltage, it is desirable that the ridge width is wider. It is especially desirable that the ridge width is increased in the region near the front facet 5 having a high light density.

(3) In order to suppress kink generation, it is desirable that the ridge width is narrower.

(4) From the standpoint of the horizontal spread angle, it is desirable that the ridge width of the red laser 1 is narrower than that of the infrared laser 2.

It can be seen from the above requirements that the ridge shape shown in FIG. 2 is desirable in order to reduce the operating current and the operating voltage and to improve the kink level.

This will be described regarding to the red laser 1. The red laser 1 has a wide, substantially uniform ridge width in the range from the front facet 5 to the position of the length L3 (the red-side front end region 40c), whereby a larger current is supplied to the region closer to the front facet 5 having a high light density. The longer the red-side front end region 40c becomes, the more the operating voltage can be reduced. In the range of the length L2 extending from the rear end 6 side of the red-side front end region 40c (the red-side tapered region 40b), the ridge width is reduced rearward from Wf1 to Wr1. The following range of the length L1 is the red-side rear end region 40a having a substantially uniform width Wr1 which is narrower than the width of the red-side front end region 40c. Since the red-side rear end region 40a contacting the rear facet 6 has a narrow width, the kink level can be increased. This effect becomes more significant as the length L1 of the red-side rear end region 50a is increased.

An optimal ridge shape for the infrared laser 2 is the same as that for the red laser 1. However, provided that the ridge width is the same, the kink level becomes higher in the infrared laser 2 than in the red laser 1 and therefore the length L4 of the infrared-side rear end region 41a which contributes to improvement in kink level can be made shorter than L1.

On the other hand, the infrared laser 2 has smaller laser light energy than that of the red laser 1 (the light energy becomes smaller as the wavelength becomes longer). Accordingly, the infrared laser 2 has smaller slope efficiency than that of the red laser 1 and therefore has a larger operating current.

Since the red laser 1 and the infrared laser 2 are integrated on the same substrate 1, the red laser 1 and the infrared laser 2 have the same cavity length. In this case, it is necessary to set the cavity length to a value suitable for the red laser 1 having poor temperature characteristics. The cavity length is therefore longer than an optimal cavity length of the infrared laser 2. As a result, the slope efficiency in the infrared laser 2 is reduced due to light loss in the ridge waveguide.

In general, when the ridge width is varied, scattering loss of guided waves at the ridge sidewalls is increased, which causes reduction in efficiency. Accordingly, in order to reduce increase in waveguide loss caused by varying the ridge width, it is desirable to gradually vary the ridge width.

In view of the above, it is important that, in the infrared laser 2, the infrared-side tapered region 41b having the ridge width varied has a longer length L5 to suppress the light loss and thereby improve the slope efficiency.

The following structure is therefore desirable in view of the above requirements for the planar shape of the ridge portions 40 and 41:

(1) In order to improve the slope efficiency, the ridge width of the front facet 5 side is wider than that of the rear facet 6 side. In other words, Wf1>Wr1 and Wf2>Wr2 are satisfied.

(2) From the standpoint of horizontal spread of emitted light, the width of the red-side front end region 40c is narrower than that of the infrared-side front end region 41c. In other words, Wf1<Wf2 is satisfied.

(3) In order to improve the kink level in the red laser 1, L1>L4 is satisfied.

(4) L3>L2 is satisfied in order to reduce the operating voltage of the red laser 1 and L5>L6 is satisfied in order to improve the slope efficiency in the infrared laser 2.

FIG. 2 shows the structure satisfying (1) through (4).

Hereinafter, the semiconductor laser device 50 will further be described as an example of the description given above.

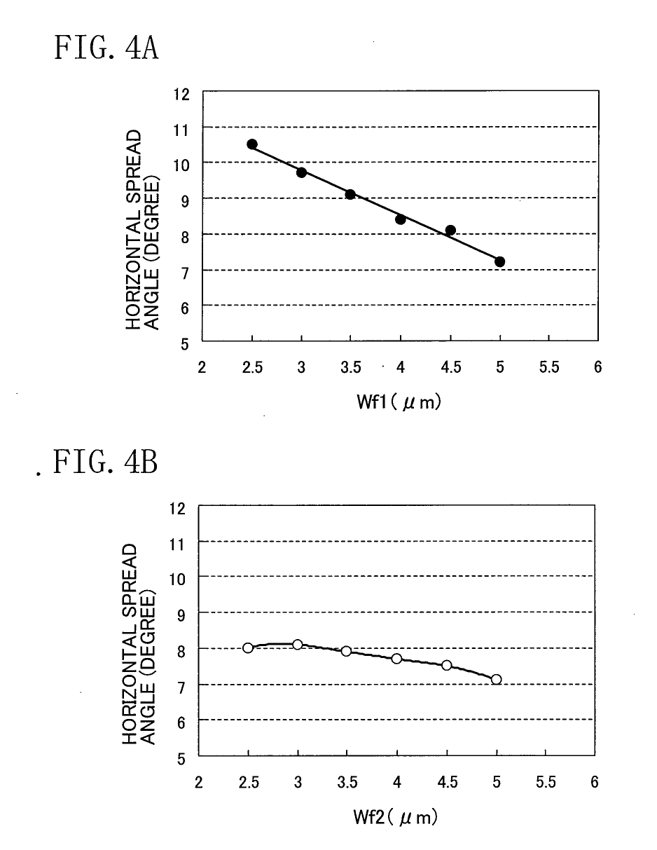

FIG. 4A shows the relation between the ridge width Wf1 at the front facet 5 and the horizontal spread angle in the red laser 1. FIG. 4B shows the relation between the ridge width Wf2 at the front facet 5 and the horizontal spread angle in the infrared laser 2. In FIGS. 4A and 4B, the semiconductor laser device 50 was pulse-driven at 80° C. (pulse width: 50 ns; duty ratio: 40%) with optical output of 400 mW.

As shown in FIGS. 4A and 4B, in this example, the horizontal spread angle is 9° in the red laser 1 and 7.5° in the infrared laser 2 when the ridge width Wf1 at the front facet 5 of the infrared laser 1 is 3.5 μm and the ridge width Wf2 at the front facet 5 of the infrared laser 2 is 4.5 μm.

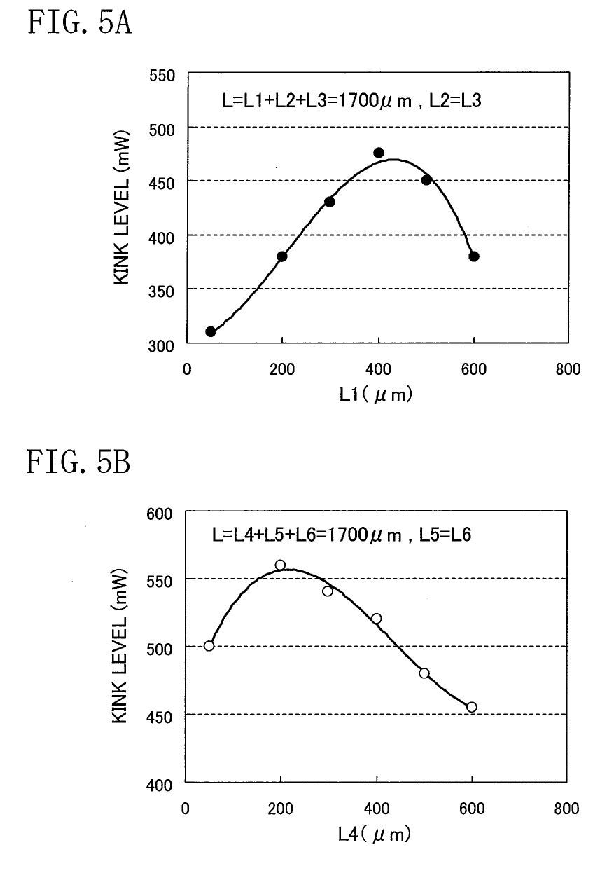

FIG. 5A shows variation in kink level obtained by varying the length L1 of the red-side rear end region 40a of the red laser 1. The cavity length is herein 1,700 μm and L2=L3. The semiconductor laser device 50 was pulse-driven at 80° C.

As shown in FIG. 5A, in the red laser 1, the kink level is increased when L1 is increased in the range up to 400 μm. However, the kink level starts to reduce when L1 exceeds 400 μm. As L1 is increased, L2 is reduced and variation in the ridge width in the red-side tapered region 40b is therefore increased. As a result, the waveguide loss is increased and the kink level is reduced.

In view of the above, in the semiconductor laser device 50, L1 is set to 400 μm corresponding to the highest king level.

FIG. 5B shows variation in kink level obtained by varying the length L4 of the infrared-side rear end region 41a of the infrared laser 2. The cavity length is herein 1,700 μm and L5=L6. The semiconductor laser device 50 was pulse-driven at 80° C. (pulse width: 50 ns; duty ratio: 40%).

As shown in FIG. 5B, in this example, a kink level of 500 mW or higher can be obtained when L4 is 200 μm. The kink level starts to reduce when L4 exceeds 200 μm. The kink level becomes about 450 mW when L4 is around 600 μm. Although such a peak is generated for the same reason as that in the red laser 1, the kink level of the infrared laser 2 is higher than that of the red laser 1. This is considered to be because the infrared laser 2 has better temperature characteristics than those of the red laser 1 and therefore has a lower operating carrier density and less spatial hole burning of carriers than those of the red laser 1.

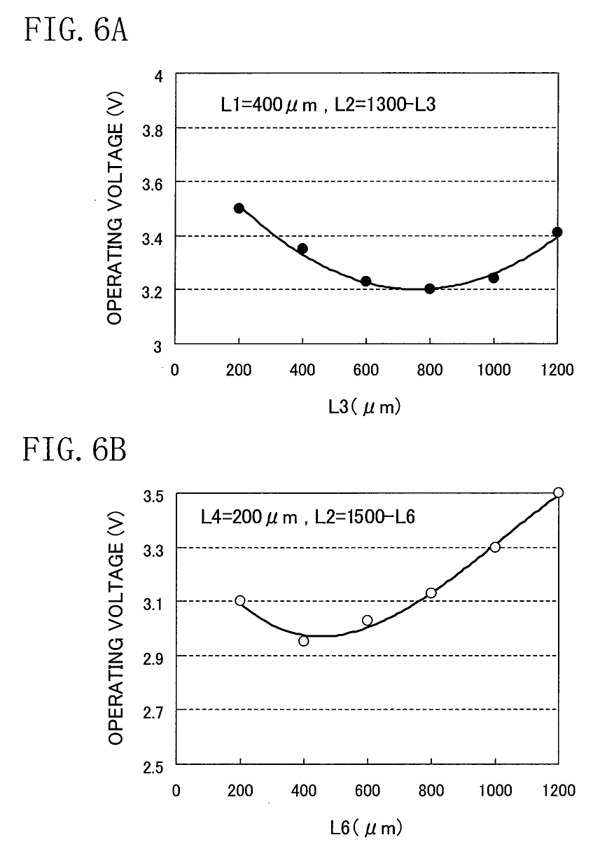

FIG. 6A shows variation in operating voltage obtained by varying the length L3 of the red-side front end region 40c of the red laser 1. The cavity length is herein 1,700 μm and L1 is 400 μm. Therefore, L2=(1,300-L3) μm. The semiconductor laser device 50 was pulse-driven at 80° C. (pulse width: 50 ns; duty ratio: 40%) with optical output of 400 mW.

As shown in FIG. 6A, in the red laser 1, the operating voltage is reduced as the length L3 is increased. However, there is an extreme value and the operating voltage is increased especially when L3 becomes 1,000 μm or longer. The reason for this is considered as follows: with increase in L3, variation in ridge width of the red-side tapered region 40b is increased. As a result, the waveguide loss is increased and the operating current value is increased. Accordingly, an appropriate range of the length L3 of the red-side front end region 40c in the red laser 1 is 600 μm to 1000 μm.

FIG. 6B shows variation in operating voltage obtained by varying the length L6 of the infrared-side front end region 41c of the infrared laser 1. The cavity length is herein 1,700 μm and L4 is 200 μm. Therefore, L5=(1,500-L6) μm. The semiconductor laser device 50 was pulse-driven at 80° C. (pulse width: 50 ns; duty ratio: 40%) with optical output of 400 mW.

As shown in FIG. 6B, in the infrared laser 2, the operating voltage becomes the smallest when the length L6 of the infrared-side front end region 41c is 400 μm. The reason why the waveguide loss increases when L6 exceeds 400 μm is the same as that in the case of the red laser 1. However, reduction in efficiency caused by the waveguide loss has a greater influence than that in the case of the red laser 1. Therefore, it is desirable that the region of the front facet 5 side in the infrared laser 2 has a shorter length than that in the red laser 1.

From the above results, in the semiconductor laser device 50 in which the red laser 1 and the infrared laser 2 have the same cavity length of 1,700 μm, L1 is set to 400 μm and L3 is set to 800 μm so that the kink level of at least 400 mW and low operating voltage characteristics can be obtained for the red laser 1. Moreover, L4 is set to 200 μm and L6 is set to 400 μm so that the kink level of at least 500 mW and low operating voltage characteristics can be obtained for the infrared laser 2.

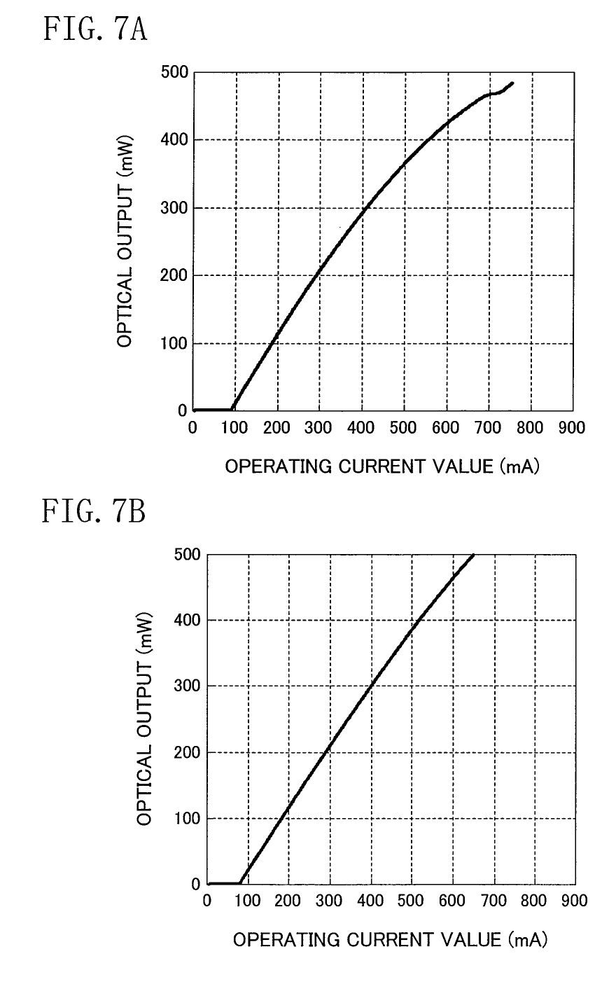

FIGS. 7A and 7B show current-optical output characteristics of the infrared laser 1 and the infrared laser 2, respectively, in the case where the semiconductor laser device 50 is pulse-driven at 80° C. with a pulse width of 50 ns and a pulse duty ratio of 40%. It can be seen from FIG. 7A that no kink is generated in the red laser 1 up to optical output of 450 mW. It can also be seen from FIG. 7B that the current-optical output characteristics of the infrared laser 2 have very good linearity and the infrared laser 2 has a kink level of 500 mW or higher.

As described above, according to the semiconductor laser device 50, improvement in kink level, reduction in operating voltage, improvement in temperature characteristics, and setting of the horizontal spread angle of emitted light can be implemented in each light emitting portion in a laser device having a plurality of light emitting portions.

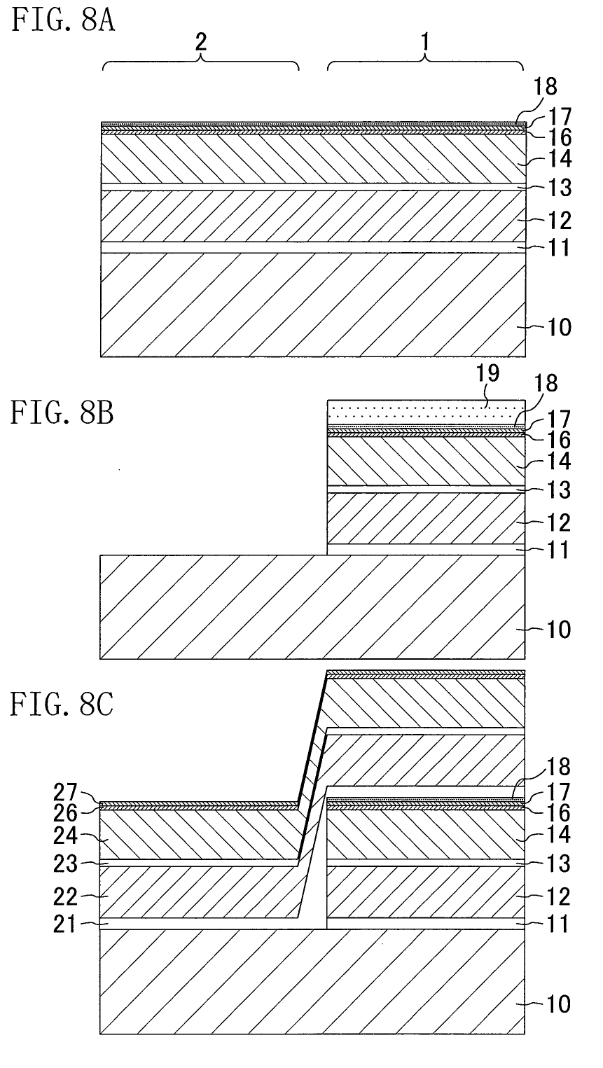

Hereinafter, a method for manufacturing the semiconductor laser device 50 will be described with reference to the figures. FIGS. 8A through 8C, FIGS. 9A through 9C, and FIGS. 10A and 10B illustrate the manufacturing method of the semiconductor laser device 50.

As shown in FIG. 8A, an n-type GaAs substrate 10 is prepared. The n-type GaAs substrate 10 has a surface tilted at 10 degrees from a (100) face in a [011] direction as a main surface. Various layers are then grown over the n-type GaAs substrate 10. More specifically, an n-type buffer layer 11 (thickness: 0.5 μm), an n-type cladding layer 12 (thickness: 2.0 μm), an active layer 13, a p-type cladding layer 14, a p-type protective layer 16 (thickness: 50 nm), a p-type contact layer 17 (thickness: 0.4 μm), and a p-type boundary film 18 (thickness: 0.05 μm) are sequentially formed on the n-type GaAs substrate 10 in this order from the bottom. The n-type buffer layer 11 is made of n-type GaAs, and the n-type cladding layer 12 is made of n-type (Al_{0.7}Ga_{0.3})_{0.51}In_{0.49}P. The active layer 13 has a strained quantum well structure. The p-type cladding layer 14 is made of p-type (Al_{0.7}Ga_{0.3})_{0.51}In_{0.49}P, the p-type protective layer 16 is made of p-type Ga_{0.51}In_{0.49}P, and the p-type contact layer 17 is made of p-type GaAs. The p-type boundary film 18 is made of Ga_{0.51}In_{0.49}P. For example, these layers can be formed by crystal growth by using an MOCVD (Metalorganic Chemical Vapor Phase Deposition) method or an MBE (Molecular Beam Epitaxy) method.

Note that the active layer 13 has a layered structure shown in FIG. 1B. This layered structure can be formed by sequentially forming a first guide layer 13g1, a well layer 13w1, a barrier layer 13b1, a well layer 13w2, a barrier layer 13b2, a well layer 13w3, and a second guide layer 13g2 in this order from the bottom. Although the active layer having a strained quantum well structure is used in this example, the present invention is not limited to this. For example, a non-strained quantum well layer may be used or a bulk active layer may be used. The active layer 13 may have either p-type conductivity or n-type conductivity. The active layer 13 may be an undoped layer.

A resist pattern 19 is formed by photolithography on the p-type boundary film 18 of the layered structure of FIG. 8A. Etching is then performed by using the resist pattern 19 as a mask. As shown in FIG. 8B, the layered structure from the n-type buffer layer 11 to the p-type boundary film 18 is thus removed in the region where no resist pattern 19 is formed, thereby exposing the n-type GaAs substrate 10. A sulfuric acid-based material or a hydrochloric acid-based material can be used as an etchant.

After the resist pattern 19 is removed, as shown in FIG. 8C, various layers are grown over the exposed n-type GaAs substrate 10 and the p-type boundary film 18 by using an MOCVD method or an MBE method. More specifically, an n-type buffer layer 21 (thickness: 0.5 μm), an n-type cladding layer 22 (thickness: 2.0 μm), an active layer 23, a p-type cladding layer 24, a p-type protective layer 26 (thickness: 50 nm), and a p-type contact layer 27 (thickness: 0.4 μm) are sequentially formed on the exposed n-type GaAs substrate 10 and the p-type boundary film 18 in this order from the bottom. The n-type buffer layer 21 is made of n-type GaAs, and the n-type cladding layer 22 is made of n-type (Al_{0.7}Ga_{0.3})_{0.51}In_{0.49}P. The active layer 23 has a quantum well structure. The p-type cladding layer 24 is made of p-type (Al_{0.7}Ga_{0.3})_{0.51}In_{0.49}P, the p-type protective layer 26 is made of p-type Ga_{0.51}In_{0.49}P, and the p-type contact layer 27 is made of p-type GaAs.

The active layer 23 has a layered structure shown in FIG. 1C. This layered structure can be formed by sequentially forming a first guide layer 23g1, a well layer 23w1, a barrier layer 23b1, a well layer 23w2, a barrier layer 23b2, a well layer 23w3, and a second guide layer 23g2 in this order from the bottom.

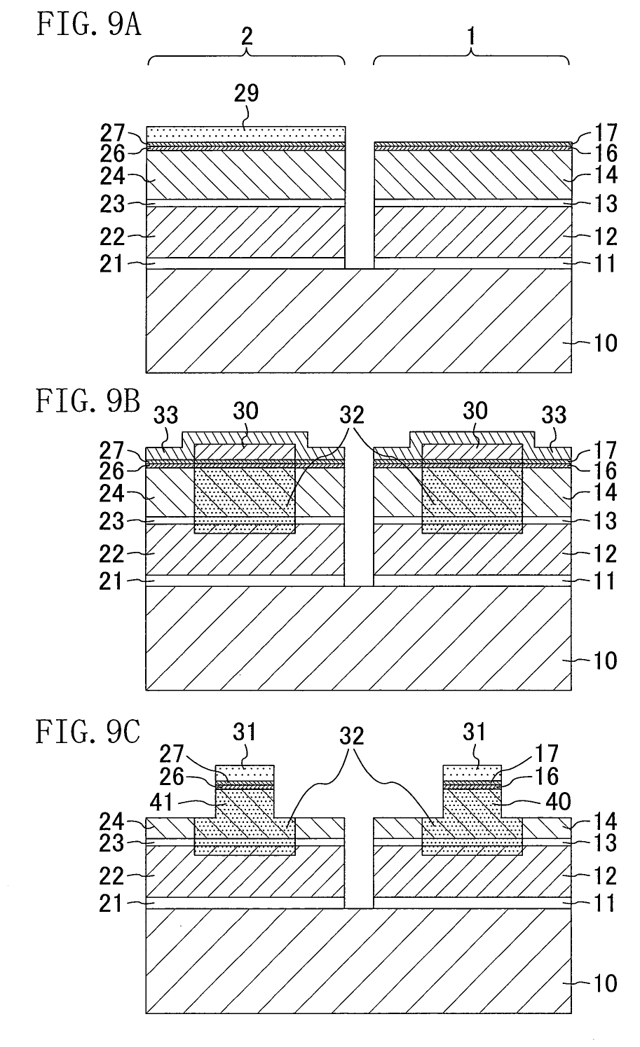

As shown in FIG. 9A, a resist pattern 29 is then formed by photolithography. By using the resist pattern 29 as a mask, the layered structure from the n-type buffer layer 21 to the p-type contact layer 27 and the p-type boundary film 18 are removed by etching in the region where no mask is formed. The resist pattern 19 is then removed.

As shown in FIG. 9B, a ZnO (zinc oxide) film of 0.3 μm thickness is then deposited on the p-type contact layers 17 and 27 by an atmospheric thermal CVD method (370° C.) or the like. Patterning is then performed by photolithography and etching to form Zn diffusion sources 30. A cap layer 33 is formed so as to cover the Zn diffusion sources 30 and the p-type contact layers 17 and 27.

Zn diffusion regions 32 are then formed by thermally diffusing Zn from the Zn diffusion sources 30. Since the surface is covered with the cap layer 33, degradation in crystallinity at the surface of the p-type contact layers 17 and 27 and thermal decomposition of the Zn diffusion sources 30 during the Zn diffusion process are suppressed. As a result, window regions can be stably formed without causing degradation in crystallinity of the waveguide in the window region. Note that the Zn diffusion regions 32 are the regions that will serve as window regions in the active layer 13 and the active layer 23. The Zn diffusion sources 30 are provided correspondingly. The window regions are formed in, for example, cavity facet portions.

The Zn diffusion sources 30 and the cap film 33 are removed after the Zn diffusion.

As shown in FIG. 9C, a silicon oxide film of 0.3 μm thickness is then deposited on the p-type contact layers 17 and 27 by an atmospheric thermal CVD method (370° C.). Patterning is then performed by photolithography and etching to form a stripe mask 31.

By using the stripe mask 31 as a mask, the p-type contact layers 17 and 27, the p-type protective layer 16 and 26, and the p-type cladding layers 14 and 24 are sequentially selectively etched to form mesa-shaped ridge portions 40 and 41 in the layered structure of a hetero structure. In addition to the ridge portions 40 and 41, the p-type cladding layers 14 and 24 are left as thinner films than before the etching.

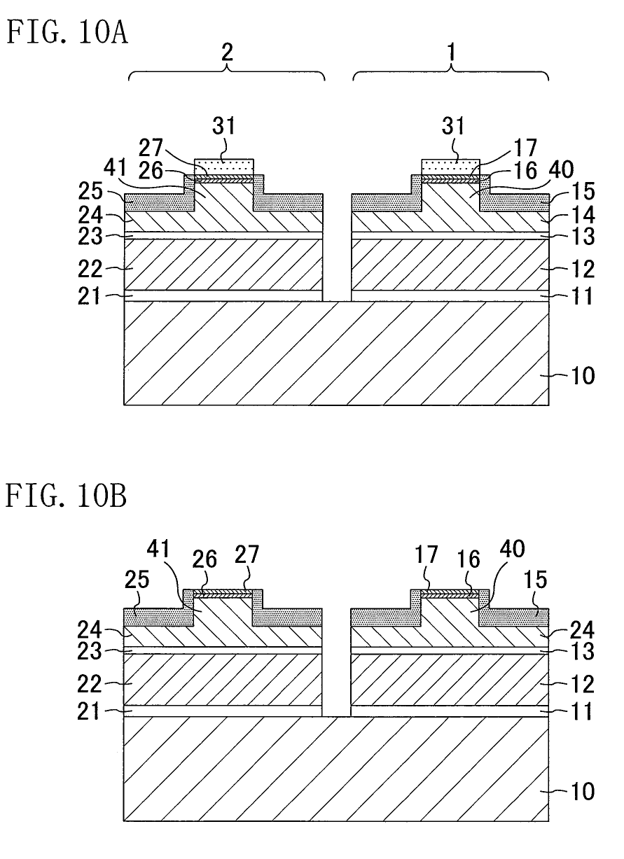

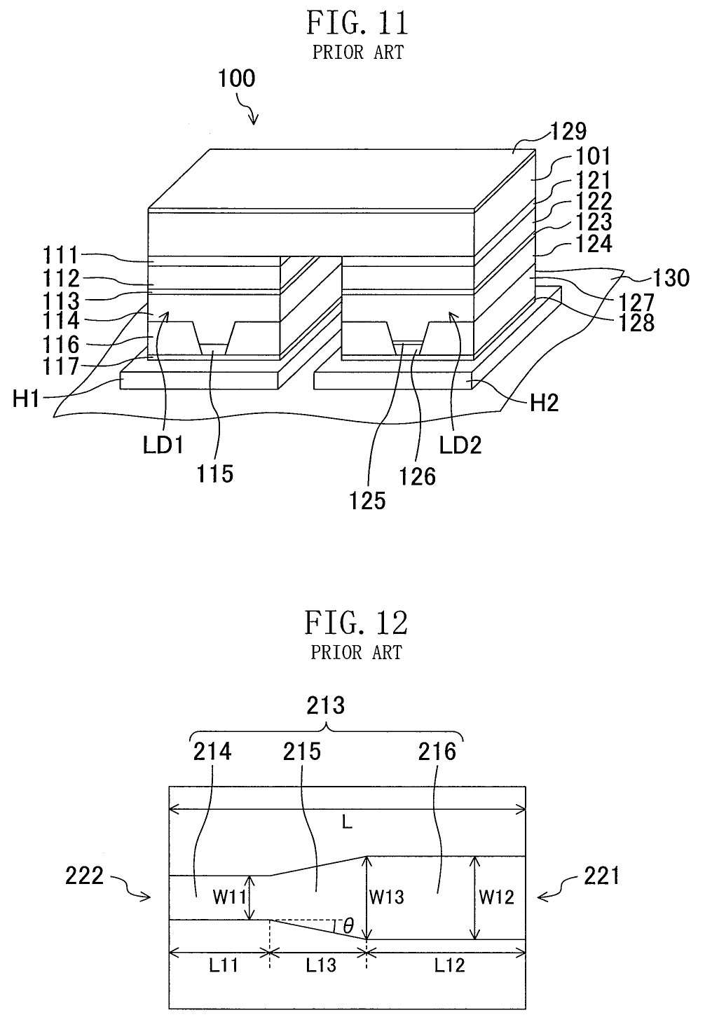

As shown in FIG. 10A, current block layers 15 and 25 made of an SiN dielectric film are then formed by a CVD method so as to cover the sidewalls of the ridge portions 40 and 41, the remaining part of the p-type cladding layers 14 and 24, and the like. Since the stripe mask 31 is still present, no current block films 15 and 25 will be formed on the p-type contact layers 17 and 27.

As shown in FIG. 10B, the stripe mask 31 is then removed by etching using a hydrofluoric acid-based etchant.

The semiconductor laser device of this example is thus manufactured. However, it should be noted that the materials, shapes, dimensions, and the like described above are given by way of example only and the present invention is not limited to them.

In the above description, crystal growth of the infrared laser portion is performed after crystal growth of the red laser portion is performed. However, crystal growth of the red laser portion may be performed after crystal growth of the infrared laser portion is performed.

What is claimed is:

1. A semiconductor laser device, comprising:
a first light emitting portion; and
a second light emitting portion that emits light at a longer wavelength than that of the first light emitting portion,
wherein the first light emitting portion and the second light emitting portion are provided on a substrate,
each of the first light emitting portion and the second light emitting portion includes a first conductive type cladding layer, an active layer formed on the first conductivity type cladding layer, and a second conductivity type cladding layer formed on the active layer and having a stripe-shaped ridge structure for carrier injection,
the ridge structure in the first light emitting portion includes
a first front end region having a width Wf1 and having a length L3 from a front facet,
a first rear end region having a width Wr1 and having a length L1 from a rear facet, and
a first tapered region located between the first front end region and the first rear end region, having a width varied from the front facet side toward the rear facet side, and having a length L2, where the relation of Wf1>Wr1 is satisfied,
the ridge structure in the second light emitting portion includes
a second front end region having a width Wf2 and having a length L6 from a front facet,
a second rear end region having a width Wr2 and having a length L4 from a rear facet, and
a second tapered region located between the second front end region and the second rear end region, having a width varied from the front facet side toward the rear facet side, and having a length L5, and the relation of Wf2>Wr2 is satisfied, where
the relations of L1+L2+L3=L4+L5+L6, Wf1<Wf2, and L1>L4 are satisfied.

2. The semiconductor laser device of claim 1, wherein the relations of L3>L2 and L5>L6 are satisfied.

3. The semiconductor laser device of claim 1, wherein, provided that Rf is a reflectance at the front facet and Rr is a reflectance at the rear facet, the relation of Rf<Rr is satisfied.

4. The semiconductor laser device of claim 1, wherein the first front end region, the first rear end region, the second front end region, and the second rear end region are shaped so that variation in width is within ±10%.

5. The semiconductor laser device of claim 1, wherein, in both of the first light emitting portion and the second light emitting portion, the first conductivity type cladding layer and the second conductivity type cladding layer are both made of an AlGaInP-based material.

6. The semiconductor laser device of claim 1, wherein the active layer in the first light emitting layer is made of a GaInP-based or AlGaInP-based material and the active layer in the second light emitting layer is made of a GaAs-based or AlGaAs-based material.

7. The semiconductor laser device of claim 1, wherein the active layer in at least one of the first light emitting portion and the second light emitting portion is a quantum well active layer, and the quantum well active layer is disordered by impurity diffusion in a vicinity of at least one of a front facet and a rear facet of a cavity including the quantum well active layer.
